(19) United States
(12) Patent Application Publication
(10) Pub. No.: US 2019/0341530 A1
(43) Pub. Date: Nov. 7, 2019

(54) WAVELENGTH CONVERTER AND WAVELENGTH CONVERSION MEMBER

(71) Applicant: Panasonic Intellectual Property Management Co., Ltd., Osaka (JP)

(72) Inventors: Tatsuya OKUNO, Osaka (JP); Masahiro NAKAMURA, Osaka (JP); Youshin LEE, Osaka (JP)

(21) Appl. No.: 16/472,884

(22) PCT Filed: Oct. 18, 2017
(86) PCT No.: PCT/JP2017/037650

§ 371 Date: Jun. 23, 2019

(30) Foreign Application Priority Data
Dec. 27, 2016 (JP) 2016-253455

(51) Int. Cl. H01L 33/50; C09K 11/08; G02B 5/20

(52) U.S. Cl. CPC H01L 33/501; H01S 5/02; G02B 5/20; C09K 11/08

(57) ABSTRACT

A wavelength converter includes: inorganic phosphor particles; translucent non-fluorescent light emitting inorganic particles; and an inorganic binder, wherein the inorganic phosphor particles and the translucent non-fluorescent light emitting inorganic particles are bound to each other by the inorganic binder, an average particle size of the translucent non-fluorescent light emitting inorganic particles is equal to or more than an average particle size of the inorganic phosphor particles, thermal conductivity of the translucent non-fluorescent light emitting inorganic particles is larger than thermal conductivity of the inorganic phosphor particles, a refractive index of the translucent non-fluorescent light emitting inorganic particles stays within a range of ±6% of a refractive index of the inorganic phosphor particles, and fluorescence is emitted upon receiving excitation light.

### TECHNICAL FIELD

The present invention relates to a wavelength converter using photoluminescence, and particularly, relates to a wavelength converter and a wavelength conversion member, which are excellent in heat dissipation and efficiency even when irradiated with high-power excitation light.

### BACKGROUND ART

Heretofore, as a wavelength converter using photoluminescence, there has been known a wavelength converter composed of: a plurality of phosphor particles which emit light by being irradiated with excitation light; and a binder that holds the plurality of phosphor particles. Specifically, a wavelength converter in which silicon resin is filled with a phosphor has been known. For example, the wavelength converter has a form of a layered or plate-shaped body formed on a metal substrate.

In recent years, the wavelength converter has been required to increase power of excitation light in order to enhance a light output. Therefore, for the wavelength converter, high-power excitation light of a laser light source or the like has been being used as the excitation light. However, such an organic binder as the silicon resin is poor in heat dissipation. Therefore, when the wavelength converter having the organic binder is irradiated with the high-power excitation light of the laser light source or the like, the organic binder is discolored and burnt to decrease light transmittance of the wavelength converter, whereby light output efficiency of the wavelength converter is prone to decrease.

Note that, though there is an example of using an inorganic binder without using the organic binder, the binder involves heat generation, whereby luminance of phosphor is prone to decrease due to temperature quenching thereof, and the light output efficiency of the wavelength converter is prone to decrease.

### CITATION LIST

### Patent Literature

PTL 1: Japanese Unexamined Patent Publication No. 2014-116587
PTL 2: Japanese Unexamined Patent Publication No. 2016-20420

### SUMMARY OF INVENTION

### Technical Problem

For this, there is conceived a method of blending a substance other than the phosphor with the wavelength converter, thereby improving thermal conductivity of the wavelength converter. For example, such a known method as described in PTL 1 and PTL 2 makes it possible to improve the thermal conductivity.

However, in this case, the substance other than the phosphor in the wavelength converter is prone to increase a probability at which an angle of an optical path of each of excitation light and fluorescence is changed due to scattering and refraction, and is prone to decrease a probability at which each of the excitation light and the fluorescence is taken from an inside of the wavelength converter to an outside thereof.

Then, a mode where each of the excitation light and the fluorescence is guided in an in-plane direction in the inside of the wavelength converter becomes more dominant, and as a result, there is a problem that light extraction efficiency decreases or that output spots increase.

As described above, heretofore, there has not been known a configuration of a wavelength converter excellent in heat dissipation and efficiency even when irradiated with the high-power excitation light.

The present invention has been made in consideration of the above-described problems. It is an object of the present invention to provide a wavelength converter and a wavelength conversion member, which are excellent in heat dissipation and efficiency even when irradiated with the high-power excitation light.

### Solution to Problem

In order to solve the above-described problems, a wavelength converter according to a first aspect of the present invention includes: inorganic phosphor particles; translucent non-fluorescent light emitting inorganic particles; and an inorganic binder, wherein the inorganic phosphor particles and the translucent non-fluorescent light emitting inorganic particles are bound to each other by the inorganic binder, an average particle size of the translucent non-fluorescent light emitting inorganic particles is equal to or more than an average particle size of the inorganic phosphor particles, thermal conductivity of the translucent non-fluorescent light emitting inorganic particles is larger than thermal conductivity of the inorganic phosphor particles, a refractive index of the translucent non-fluorescent light emitting inorganic particles stays within a range of ±6% of a refractive index of the inorganic phosphor particles, and fluorescence is emitted upon receiving excitation light.

In order to solve the above-described problems, a wavelength conversion member according to a second aspect of the present invention includes: a substrate having a reflecting surface; and the above-described wavelength converter supported on the substrate.

### BRIEF DESCRIPTION OF DRAWINGS

FIG. 1 is an example of a scanning electron micrograph (SEM) of nanoparticles of aluminum oxide for use in Example 1.

FIG. 2 is an example of an XRD spectrum of the nanoparticles of the aluminum oxide for use in Example 1.

FIG. 3 is an example of a photograph of a cross section observed by a scanning electron microscope (SEM), the cross section being obtained by cutting the wavelength conversion member obtained in Example 1 in a thickness direction.

FIG. 4 is an example of a photograph of a cross section obtained by enlarging a part of FIG. 3.

### DESCRIPTION OF EMBODIMENTS

A description will be given of a wavelength converter and a wavelength conversion member according to this embodiment.

### (Wavelength Conversion Member)

The wavelength conversion member includes: a substrate having a reflecting surface; and a wavelength converter supported on this substrate.

### (Substrate)

The substrate has roles of reinforcing the wavelength converter formed on a surface thereof, and of dissipating heat generated in an inside of the wavelength converter.

As the substrate, for example, there can be used a translucent one such as glass and sapphire and a non-translucent one such as aluminum and copper. When the substrate has translucency, it becomes possible to apply light via the substrate to phosphor particles in the wavelength converter. Herein, the fact that a material has transparency means that the material is transparent with respect to the visible light (with a wavelength of 380 nm to 800 nm). Moreover, the fact that the material is transparent means that an absorption coefficient for the visible light by the material is 0.1 or less. Moreover, it is preferable that the absorption coefficient for the visible light by the material for use in the substrate be as low as possible since it is possible to sufficiently apply light via the substrate to the phosphor particles in the wavelength converter.

Note that, when the substrate does not have translucency, the surface of the substrate becomes a reflecting surface for reflecting light, which is emitted from the wavelength converter, by the substrate. That is, the substrate may have a reflecting surface on the surface. Herein, the reflecting surface means a surface on which the visible light is reflected with high reflectance. Moreover, high reflectance means reflectance of 80% or more. Note that the reflecting surface may be the surface itself of the substrate or a surface of another member than the substrate, the surface being provided on the surface of the substrate. As such another member, for example, a multilayer film to be described later is used.

When the substrate has a reflecting surface on the surface, light emitted from the wavelength converter formed on the surface of the substrate is reflected on the reflecting surface of such a substrate surface and is guided through the inside of the wavelength converter, and accordingly, is prone to be affected by light scattering and refraction in the wavelength converter. In a wavelength converter according to the embodiment, a difference between refractive indices of translucent non-fluorescent light emitting inorganic particles and inorganic phosphor particle stay within a range of ±6%, that is, numerical values of the refractive indices are approximate to each other. Therefore, even if the light emitted from the wavelength converter is reflected on the reflecting surface of the substrate surface, such influences from the light scattering and refraction in the wavelength converter can be reduced.

The reflecting surface is, for example, made of metal or a multilayer film. Herein, the multilayer film means a film formed by laminating two or more thin films having translucency and different refractive indices on one another.

For example, aluminum is used as the metal that constitutes the reflecting surface. It is preferable that the metal that constitutes the reflecting surface have high reflectance to the visible light since light extraction efficiency of the wavelength converter and the wavelength conversion member is improved.

As the multilayer film, specifically, used is a film formed by laminating plural types of thin films, each of which is made of a metal oxide such as aluminum oxide having translucency, or the like. It is preferable that the reflecting surface be made of the metal or the multilayer film since the light extraction efficiency of the wavelength converter and the wavelength conversion member is improved.

### (Wavelength Converter)

The wavelength converter is composed of inorganic phosphor particles, translucent non-fluorescent light emitting inorganic particles and an inorganic binder. The inorganic phosphor particles and the translucent non-fluorescent light emitting inorganic particles are bound to each other by the inorganic binder.

### <Inorganic Phosphor Particle>

The inorganic phosphor particles are particles of an inorganic compound capable of photoluminescence. A type of the inorganic phosphor particles is not particularly limited as long as the inorganic phosphor particles are capable of photoluminescence. As the inorganic phosphor particles, for example, used are crystalline particles with a garnet structure made of YAG, that is, Y₃Al₅O₁₂, and phosphor particles made of (Sr,Ca)AlSiN₃:Eu.

An average particle size of the inorganic phosphor particles usually ranges from 1 to 10 μm, preferably ranges from 11 to 30 μm. It is preferable that the average particle size of the inorganic phosphor particles stay within the above-described range since the inorganic phosphor particles are producible by an inexpensive production process such as an application method and it is relatively easy to adjust chromaticity thereof.

The average particle size of the inorganic phosphor particles is obtained by observing an arbitrarily preprocessed wavelength converter by a scanning electron microscope (SEM) or the like and obtaining an average value of diameters of inorganic phosphor particles of which number is sufficiently significant from a statistical viewpoint, for example, 100.

Moreover, it is possible to determine a composition of the inorganic phosphor particles by a known analysis method such as energy dispersive X-ray analysis (EDX) and X-ray diffraction analysis (XRD).

The inorganic phosphor particles may be made of a single type of phosphor having the same composition, or may be a mixture of phosphor particles having two or more types of compositions.

### <Inorganic Binder>

The inorganic binder just needs to be capable of binding at least two inorganic phosphor particles to each other, and a type thereof is not particularly limited. For example, alumina, silica or the like is used as the inorganic binder.

As the inorganic binder, for example, used is an aggregate of inorganic nanoparticles (that is, a fixed body of inorganic nanoparticles). Specifically, as the inorganic binder, there can be used a fixed body of inorganic nanoparticles with an average particle size of approximately 100 nm, the inorganic nanoparticles having air gaps. The fixed body of the inorganic nanoparticles means a solid of the inorganic nanoparticles, which is directly formed by covalent bond or formed thereby via grain boundary phases. When the inorganic binder is the fixed body of the inorganic nanoparticles, this fixed body of the inorganic nanoparticles binds the inorganic phosphor particles and the above-described translucent non-fluorescent light emitting inorganic particles to each other.

As the fixed body of the inorganic nanoparticles, for example, used are: an alumina fixed body formed by fixing a large number of alumina nanoparticles to one another; and a silica fixed body formed by fixing a large number of silica nanoparticles to one another. The alumina fixed body is obtained, for example, such that alumina nanoparticles in alumina sol are fixed to one another. The silica fixed body is obtained, for example, such that silica nanoparticles in silica sol are fixed to one another.

When the inorganic binder is the fixed body of the inorganic nanoparticles, an average particle size of the inorganic nanoparticles which constitute the fixed body ranges from 50 to 200 nm for example, preferably ranges from 80 to 150 nm. It is preferable that the average particle size of the inorganic nanoparticles stay within the above-described range since adhesion between the inorganic nanoparticles and the substrate is improved.

It is desirable that thermal conductivity of the inorganic binder be, for example, 1 w/mK or more. When the thermal conductivity of the inorganic binder stays within this range, heat dissipation of the wavelength converter is good.

The inorganic binder can be produced by a known method, for example, such as a method using the sol-gel method and a method using the aerosol deposition.

The inorganic binder may be made of a single type of inorganic binder having the same composition, or may be a mixture of inorganic binders having two or more types of compositions.

### <Translucent Non-Fluorescent Light Emitting Inorganic Particle>

The translucent non-fluorescent light emitting inorganic particles mean inorganic metal oxide particles which are transparent in the visible light region (with a wavelength of 380 nm to 800 nm) and do not emit fluorescence or light by being excited by light with the wavelength in the visible light region. Here, the fact that the inorganic metal oxide particles are transparent in the visible light region means that an absorption coefficient for light in the visible light region is extremely small. Specifically, the fact that the inorganic metal oxide particles are transparent in the visible light region means that the absorption coefficient for the visible light by the material is 0.1 or less. It is preferable that the translucent non-fluorescent light emitting inorganic particles be transparent in the visible light region since the light extraction efficiency is improved. Moreover, the phrase “do not emit fluorescence by being excited by light with the wavelength in the visible light region” means that neither fluorescence nor light is emitted even if irradiated with the light in the above-described visible light region with the wavelength of 380 nm to 800 nm.

As will be described later, thermal conductivity of the translucent non-fluorescent light emitting inorganic particles is larger than the thermal conductivity of the inorganic phosphor particles. The wavelength converter according to the embodiment includes the translucent non-fluorescent light emitting inorganic particles in addition to the inorganic phosphor particles, and accordingly, has higher heat dissipation than in the case of not including the translucent non-fluorescent light emitting inorganic particles.

Moreover, as will be described later, a refractive index of the translucent non-fluorescent light emitting inorganic particles stays within the range of ±6% of a refractive index of the inorganic phosphor particles, and is less different from the refractive index of the inorganic phosphor particles. The wavelength converter according to the embodiment includes the translucent non-fluorescent light emitting inorganic particles in addition to the inorganic phosphor particles; however, optical characteristics thereof do not change much from the case of not including the translucent non-fluorescent light emitting inorganic particles.

For example, alumina is mentioned as a material for use in the translucent non-fluorescent light emitting inorganic particles. It is preferable that the material for use in the translucent non-fluorescent light emitting inorganic particles be alumina since thermal conductivity thereof is high.

An average particle size of the translucent non-fluorescent light emitting inorganic particles usually ranges from 1 to 100 μm, preferably ranges from 11 to 30 μm. It is preferable that the average particle size of the translucent non-fluorescent light emitting inorganic particles stay within the above-described range since the translucent non-fluorescent light emitting inorganic particles are producible by an inexpensive production process such as an application method and it is relatively easy to adjust chromaticity thereof. It is possible to analyze the average particle size and composition of the translucent non-fluorescent light emitting inorganic particles by the same method as the above-described measurement method for the average particle size and composition of the inorganic phosphor particles.

The translucent non-fluorescent light emitting inorganic particles may be made of a single type of translucent non-fluorescent light emitting inorganic particles having the same composition, or may be a mixture of translucent non-fluorescent light emitting inorganic particles having two or more types of compositions.

### <Shapes of Inorganic Phosphor Particles and Translucent Non-Fluorescent Light Emitting Inorganic Particles>

It is desirable that, in the wavelength converter, at least a part of particles among large numbers of the inorganic phosphor particles and the translucent non-fluorescent light emitting inorganic particles, which constitute the wavelength converter, have a spherical shape or a polyhedral particle shape derived from a crystal structure of garnet. Herein, the polyhedral particle shape derived from the crystal structure of the garnet means a polyhedral shape derived from the crystal structure of the garnet and having facets. More specifically, the polyhedral particle shape derived from the crystal structure of the garnet means that the polyhedral inorganic phosphor particles have a rhombic dodecahedron shape, or a biased polyhedron shape, or a shape in which edge portions connecting the facets to one another are rounded in each of these shapes. Hereinafter, the “polyhedral particle shape derived from the crystal structure of the garnet” will also be referred to as a “garnet-derived polyhedral shape”.

Moreover, “at least a part of the particles has a spherical shape or a polyhedral particle shape derived from the crystal structure of the garnet” means that at least a part of particles are spherical particles or particles having the garnet-derived polyhedral shape. Here, “at least a part of the particles” means one or more particles, and in usual, means a plurality of particles. In usual, the wavelength converter includes a large number of the inorganic phosphor particles and a large number of the translucent non-fluorescent light emitting inorganic particles. Therefore, the wavelength converter sometimes includes both of the spherical particles and the particles having the garnet-derived polyhedral shape.

The reason why it is desirable that at least a part of the particles among the large numbers of inorganic phosphor particles and translucent non-fluorescent light emitting inorganic particles have the spherical shape or the polyhedral particle shape derived from the crystal structure of garnet is as follows. For example, scale-shaped particles are different in terms of optical behavior from the spherical particles and the particles with the polyhedral particle shape derived from the crystal structure of the garnet. Therefore, when the above-described at least a part of particles are the spherical particles or the particles with the polyhedral particle shape derived from the crystal structure of the garnet, then portions with a similar optical behavior are formed in the wavelength converter, whereby a wavelength converter excellent in light emission efficiency is obtained. Moreover, the translucent non-fluorescent light emitting inorganic particles have higher thermal conductivity than the inorganic phosphor particles. Therefore, the wavelength converter according to this embodiment, which includes the inorganic phosphor particles and the translucent non-fluorescent light emitting inorganic particles, becomes a wavelength converter superior in heat dissipation to a wavelength converter that does not include the translucent non-fluorescent light emitting inorganic particles.

### (Relationship in Average Particle Size Between Translucent Non-Fluorescent Light Emitting Inorganic Particles and Inorganic Phosphor Particles)

The average particle size of the translucent non-fluorescent light emitting inorganic particles is equal to or more than the average particle size of the inorganic phosphor particles. It is preferable that the average particle size of the translucent non-fluorescent light emitting inorganic particles be equal to or more than the average particle size of the inorganic phosphor particles since the heat dissipation of the wavelength converter and the wavelength conversion member is improved.

### (Relationship in Thermal Conductivity Between Translucent Non-Fluorescent Light Emitting Inorganic Particles and Inorganic Phosphor Particles)

The thermal conductivity of the translucent non-fluorescent light emitting inorganic particles is larger than the thermal conductivity of the inorganic phosphor particles. It is preferable that the thermal conductivity of the translucent non-fluorescent light emitting inorganic particles be larger than the thermal conductivity of the inorganic phosphor particles since the heat dissipation of the wavelength converter and the wavelength conversion member is improved.

### (Relationship in Refractive Index Between Translucent Non-Fluorescent Light Emitting Inorganic Particles and Inorganic Phosphor Particles)

The refractive index of the translucent non-fluorescent light emitting inorganic particles stays within the range of ±6% of the refractive index of the inorganic phosphor particles. It is preferable that the refractive index of the translucent non-fluorescent light emitting inorganic particles stay within the range of ±6% of the refractive index of the inorganic phosphor particles since the light extraction efficiency of the wavelength converter and the wavelength conversion member is improved.

### (Fluorescence of Wavelength Converter)

The wavelength converter according to the embodiments emits fluorescence upon receiving excitation light. Known excitation light can be used as the excitation light.

### (Production Method of Wavelength Converter and Wavelength Conversion Member)

The wavelength converter according to this embodiment is formed on the substrate, whereby a wavelength conversion member composed of the substrate and the wavelength converter can be produced. For example, a nanoparticle-mixed solution containing the inorganic phosphor particles, the translucent non-fluorescent light emitting inorganic particles and the inorganic binder is applied on the reflecting surface of the substrate, followed by natural drying, whereby the wavelength converter according to this embodiment is formed on the reflecting surface of the substrate. In usual, the wavelength converter is supported on the reflecting surface of the substrate by being bound on the reflecting surface of the substrate by the inorganic binder. As described above, when the wavelength converter is bound to the reflecting surface of the substrate, the wavelength conversion member composed of the substrate having the reflecting surface and the wavelength converter supported on this substrate can be produced.

### (Function of Wavelength Conversion Member)

Functions of the wavelength conversion member will be described. The functions of the wavelength conversion member change depending on whether the substrate has optical transparency. For example, when a substrate that does not have the optical transparency is used as the substrate, then in the wavelength conversion member, secondary light of the inorganic phosphor particles, which is generated in the wavelength converter, is radiated from a front surface side of the wavelength converter. Meanwhile, when a substrate that has the optical transparency is used as the substrate, then in the wavelength conversion member, the secondary light of the inorganic phosphor particles, which is generated in the wavelength converter, is radiated from the front surface side of the wavelength converter and from a front surface side of the substrate.

### (Effects of Wavelength Converter and Wavelength Conversion Member)

The wavelength converter and the wavelength conversion member according to the above-described embodiment are excellent in heat dissipation and efficiency even when irradiated with the high-power excitation light.

The effects will be specifically described. In the wavelength converter according to this embodiment, the average particle size of the translucent non-fluorescent light emitting inorganic particles is equal to or more than the average particle size of the inorganic phosphor particles, and the translucent non-fluorescent light emitting inorganic particles have the refractive index of ±6% of the refractive index of the inorganic phosphor particles. Therefore, in the wavelength converter according to this embodiment, the probability at which the angle of the optical path is changed due to the scattering or refraction of the excitation light and the fluorescence in the inside of the wavelength converter becomes equivalent to the conventional one.

Hence, in the wavelength converter according to this embodiment, in the inside of the wavelength converter, the probability at which the angle of the optical path of each of the excitation light and the fluorescence is changed due to the scattering or the refraction can be decreased, and as a result, it is possible to improve the light extraction efficiency and to reduce the output spots.

Moreover, in the wavelength converter according to this embodiment, the translucent non-fluorescent light emitting inorganic particles have larger thermal conductivity than the inorganic phosphor particles, and form an inorganic phosphor film. Therefore, the wavelength converter according to this embodiment has higher heat dissipation than the conventional wavelength converter.

From the above, the wavelength converter according to this embodiment and the wavelength conversion member including this wavelength converter are excellent in heat dissipation and efficiency even when irradiated with the high-power excitation light.

### EXAMPLES

Hereinafter, this embodiment will be described more in detail by examples; however, this embodiment is not limited to these examples.

### Example 1

### (Preparation of Nanoparticle-Mixed Solution)

First, as inorganic phosphor particles, YAG particles (YAG374A165 produced by Nemoto Lumi Material Co., Ltd.; thermal conductivity: 10 W/mK; refractive index: 1.80) with an average particle size Dso of approximately 20.5 μm were prepared. Moreover, as a raw material containing nanoparticles as an inorganic binder, prepared was an aqueous solution into which nanoparticles of aluminum oxide (Al₂O₃) with an average particle size D₅₀ of approximately 20 nm were dispersed. Moreover, as translucent non-fluorescent light emitting inorganic particles, prepared were particles of aluminum oxide (thermal conductivity: 30 W/mK; refractive index: 1.75) with an average particle size D₅₀ of 30 μm. The above-described YAG particles and the above-described translucent non-fluorescent light emitting inorganic particles were added to and kneaded with the aqueous solution in which the nanoparticles of the aluminum oxide were dispersed, whereby a nanoparticle-mixed solution was produced.

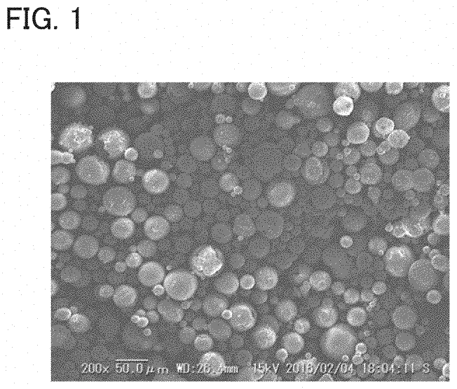

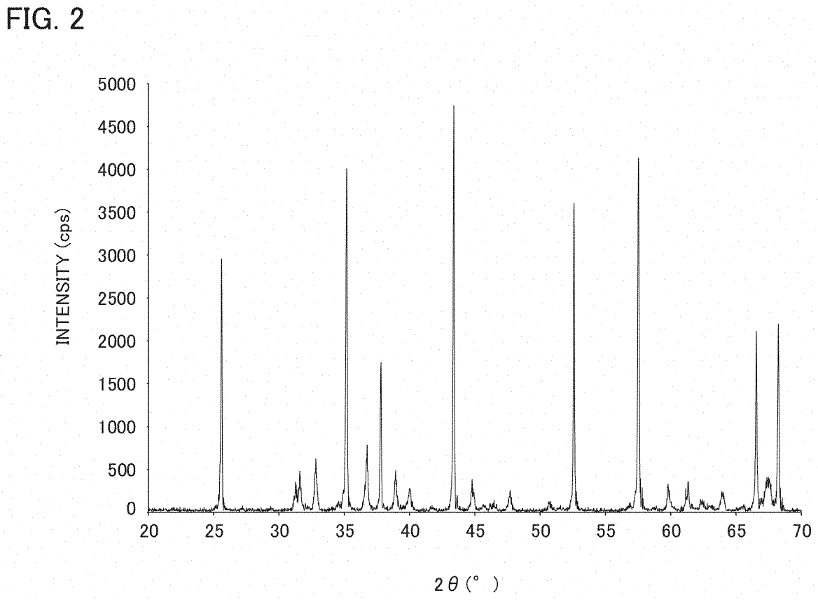

FIG. 1 is an example of a scanning electron micrograph (SEM) of the above-described nanoparticles of the aluminum oxide (Al₂O₃). FIG. 2 is an example of an XRD spectrum of the above-described nanoparticles of the aluminum oxide (Al₂O₃).

### (Application of Nanoparticle-Mixed Solution)

A tape is mounted onto a metal substrate made of aluminum to form a step difference. The nanoparticle-mixed solution was dropped to a portion surrounded by the step difference, and subsequently, the nanoparticle-mixed solution was applied using an applicator equipped with a bar coater.

### (Formation of Wavelength Converter)

The metal substrate applied with the nanoparticle-mixed solution was naturally dried. Then, a dried body having a film thickness of 100 μm was obtained. This dried body became a wavelength converter including: YAG particles; aluminum oxide particles as the translucent non-fluorescent light emitting inorganic particles; and a binder layer that fixes the YAG particles and the translucent non-fluorescent light emitting inorganic particles to each other. In this way, a wavelength conversion member in which the film-like wavelength converter with a thickness of 100 μm was formed on the metal substrate was obtained.

### (Evaluation)

### <Microscopy>

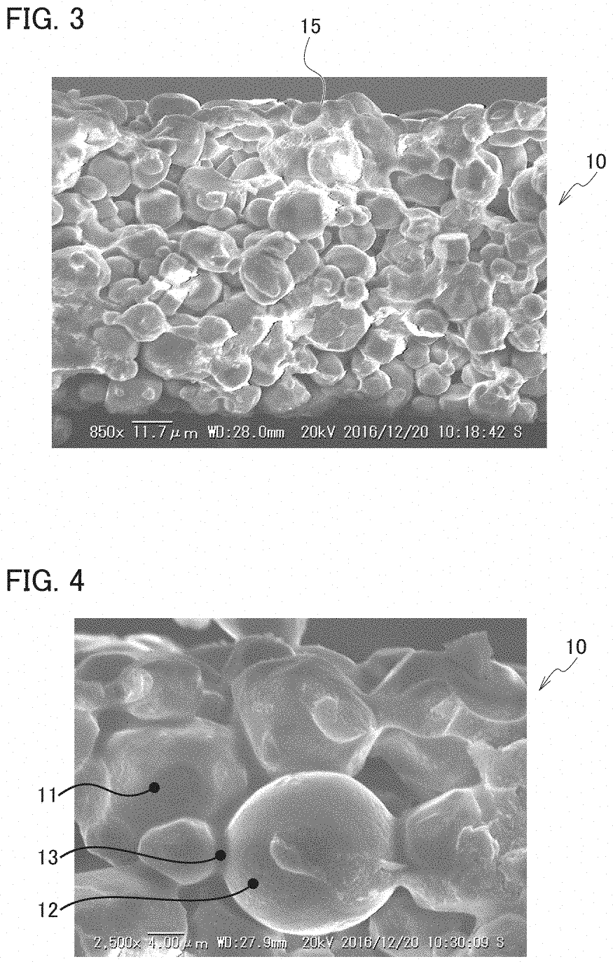

FIG. 3 is an example of a photograph of a cross section observed by a scanning electron microscope (SEM), the cross section being obtained by cutting the wavelength conversion member obtained in Example 1 in a thickness direction. In FIG. 3, a flat portion shown on an upper side thereof is a surface 15 of a wavelength converter 10 that constitutes the wavelength conversion member. Moreover, FIG. 4 is an example of a photograph of a cross section obtained by enlarging a part of FIG. 3.

As shown in FIG. 3 and FIG. 4, in the wavelength converter 10, YAG particles 11 on which facets can be confirmed and aluminum oxide particles 12 as spherical translucent non-fluorescent light emitting inorganic particles on which facets cannot be confirmed are bond to each other via an inorganic binder 13.

Therefore, in the wavelength converter 10, at least YAG particles 11 shown in FIG. 4 among a large number of the YAG particles which constitute the wavelength converter 10 have a polyhedral particle shape (a garnet-derived polyhedral shape) derived from the crystal structure of the garnet, which has facets.

Moreover, in the wavelength converter 10, at least aluminum oxide particles 12 shown in FIG. 4 among a large number of the aluminum oxide particles which constitute the wavelength converter 10 become spherical.

Hence, it has been seen that, in the wavelength converter 10, the YAG particles 11 and the aluminum oxide particles 12, which are at least a part of particles among the large number of YAG particles and the large number of aluminum oxide particles, which constitute the wavelength converter 10, have the spherical shape or the garnet-derived polyhedral shape.

The entire contents of Japanese Patent Application No. 2016-253455 (filed on: Dec. 27, 2016) are incorporated herein by reference.

Although the contents of this embodiment have been described above in accordance with the examples, it is obvious to those skilled in the art that this embodiment is not limited to the description of these and that various modifications and improvements are possible.

### INDUSTRIAL APPLICABILITY

In accordance with the present invention, there can be provided the wavelength converter and the wavelength conversion member, which are excellent in heat dissipation and efficiency even when irradiated with the high-power excitation light.

### REFERENCE SIGNS LIST

10 WAVELENGTH CONVERTER
11 YAG PARTICLES (INORGANIC PHOSPHOR PARTICLES)
12 ALUMINUM OXIDE PARTICLES (TRANSLUCENT NON-FLUORESCENT LIGHT EMITTING INORGANIC PARTICLES)
13 INORGANIC BINDER
15 SURFACE OF WAVELENGTH CONVERTER

1. A wavelength converter comprising:
inorganic phosphor particles;
translucent non-fluorescent light emitting inorganic particles; and
an inorganic binder,
wherein the inorganic phosphor particles and the translucent non-fluorescent light emitting inorganic particles are bound to each other by the inorganic binder,
an average particle size of the translucent non-fluorescent light emitting inorganic particles is equal to or more than an average particle size of the inorganic phosphor particles,
thermal conductivity of the translucent non-fluorescent light emitting inorganic particles is larger than thermal conductivity of the inorganic phosphor particles,
a refractive index of the translucent non-fluorescent light emitting inorganic particles stays within a range of ±6% of a refractive index of the inorganic phosphor particles, and
fluorescence is emitted upon receiving excitation light.

2. The wavelength converter according to claim 1, wherein at least a part of particles among large numbers of the inorganic phosphor particles and the translucent non-fluorescent light emitting inorganic particles, which constitute the wavelength converter, have a spherical shape or a polyhedral particle shape derived from a crystal structure of garnet.

3. A wavelength conversion member comprising:
a substrate having a reflecting surface; and
the wavelength converter according to claim 1, which is supported on the substrate.

4. The wavelength conversion member according to claim 3, wherein the reflecting surface is composed of metal or a multilayer film.
